(19) United States
(12) Patent Application Publication
(10) Pub. No.: US 2024/0250226 A1
(43) Pub. Date: Jul. 25, 2024

(54) LAYERED CIRCUIT WITH VERTICAL LED-PHOTODIODE COMMUNICATIONS

(71) Applicant: Nthdegree Technologies Worldwide Inc., tEMPE, AZ (US)

(72) Inventors: William J Ray, Fountain Hills, AZ (US); Brian D Ogonowsky, Mountain View, CA (US)

(21) Appl. No.: 18/099,811

(22) Filed: Jan. 20, 2023

(51) Int. Cl. H01L 33/62

(52) U.S. Cl. CPC H01L 33/62

(57) ABSTRACT

Thin, flexible substrates have printed components or conductors on them forming planarized circuit layers. One or more of the circuits may be programmable, such as with a patterned printed conductive layer, so that one generic design may be used for many different types of functions. Instead of metal vias communicating vertically between the layers, the generic layers have one or more LEDs and photodiodes that generally face each other and communicate by light pulses. Near field communications may also be used for the vertical communications. This allows the separate layers to be combined in various ways, depending on the desired function of the overall product, without requiring the steps of forming holes, filling the holes with a metal, and then connecting the metal vias together, which may form unreliable connections when the layers are flexed. The input/output signals may also be by light or NFC.

### FIELD OF THE INVENTION

This invention relates to laminating thin layers of circuits and vertically communicating between layers using wireless communications, such as LEDs and photodiodes or near field communications, and, also, to forming stackable programmable generic circuits utilizing such wireless communications.

### BACKGROUND

Applicant has previously invented a programmable circuit that uses printed semiconductor components to form logic gates, where the gates are then programmed for a custom use. That invention is described in U.S. Pat. Nos. 9,913,371 and 10,499,499, incorporated by reference. By forming a generic circuit that can be customized, the cost per device is inexpensive, compared to forming a specialized circuit. Further, since the components are printed on a thin substrate under atmospheric conditions, the cost is further reduced. The printed components may be microscopic transistors, LEDs, diodes, or other devices, that are suspended in a liquid medium and printed using screen printing, inkjet printing, flexography, or other known methods. For example, small dots of identical components, such as transistors, are printed, and the components in a single dot are connected in parallel by printing insulated conductive layers contacting the terminals of the components. Therefore, each dot effectively forms a single component. The dots may then be interconnected using another printed conductor pattern to form a customized circuit to carry out, for example, a complex logic function.

For more complex circuits, including those using one or more integrated circuits that are placed at predetermined locations on a substrate, layers of circuits may be vertically stacked to minimize the circuit's footprint, and the various layers may use metal vias to communicate in the vertical direction. It is difficult to form the vias and ensure a reliable connection between the layers. Further, equipment to deposit the metal in the via holes and then bond the vias together add significant cost and may subject the circuits to high temperatures. Still further, any bending of the layered substrates places stress on the vias, causing them to form open circuits.

What is needed is a technique that is easily adaptable to printing components on thin substrates, where multiple layers may be stacked and where metal vias are not needed to communicate between the layers in the vertical direction. Further, such a technique should allow the formation of generic circuits that can be customizable for the user's particular need.

### SUMMARY

In one embodiment, flexible substrates have printed components on them forming circuits. Integrated circuits may also be located on one or more of the substrates. The substrates are planarized. One or more of the circuits may be programmable, such as with a patterned printed conductive layer, so that one generic design may be used for many different types of functions. Each layer may include two power terminals, such as on the side, or one or all circuit layers may include a thin printed battery.

Where no external battery is needed, no external electrical contacts are needed. The battery or batteries may be charged wirelessly using RF inductive coupling.

The substrates may be highly flexible and may be the size of a credit card or a small patch.

Instead of metal vias communicating vertically between the layers, the layers have one or more LEDs and photodiodes that generally face each other and communicate by light pulses. The LEDs may be laser diodes or non-laser diodes. The layers may be transparent and extremely thin so the light passes through multiple layers. Near field communications (NFC), using flat inductive coils, may also be used for the vertical communications. This allows the separate layers to be combined in various ways, depending on the desired function of the overall product, without requiring the steps of forming holes, filling the holes with a metal, and then connecting the metal vias together.

The input/output signals may also be by light or NFC. For example, if IR is desired for input or output (or for vertical communication between layers), an IR LED or IR photodiode (or other sensor) is used. Smartphones are equipped with IR detectors and IR transmitters. A smartphone camera can also detect light pulses (such as blue or white light) from an input/output layer of the stack of layers. The smartphone flash can also communicate optically with the stack of layers. Accordingly, the stack of layers may communicate with a smartphone or with the internet via the smartphone.

The invention allows different generic circuit layers to be customized and then laminated under pressure and low heat to form the resulting circuit. The circuit may resemble a credit card or a flexible small patch.

The circuit may include an LED display layer, a battery power layer, a driver layer, an RF or optical communication layer, and other layers that perform other functions. Examples of other layers may be a biological sensor layer, an RFID layer, an input/output layer, a gas sensor layer, etc.

Other embodiments are disclosed.

### BRIEF DESCRIPTION OF THE DRAWINGS

FIG. 1 is a perspective view of a stack of five laminated layers that communicate wirelessly between them.

FIG. 2 illustrates an example of a device layer in the stack of FIG. 1 that includes programmable electronics.

FIG. 3 illustrates an example of a display layer in the stack of FIG. 1 that creates alpha-numerical images.

FIG. 4 illustrates the stack of FIG. 1 but having metal vertical vias extending through the layers for conducting power from a battery in one of the layers or from an external power source.

FIG. 5 is a cross-section of one type of device layer that is formed using printed layers of conductors and printed microscopic semiconductor components to perform a desired function. The device layer may be a generic layer that is programmed for a particular use prior to lamination to other layers.

FIG. 6 illustrates an example of a printed area containing microscopic semiconductor devices that are connected in parallel by conductive layers.

Similar or identical elements are identified with the same numerals in the various figures.

### DETAILED DESCRIPTION

In one embodiment, the invention can be used to form a flexible and small device containing stacked circuits. Examples of circuit layers include a printed LED display, LED drive circuitry, an RF (e.g., Bluetooth) or optical communication layer, a control circuit layer, and a sensor layer, such as for detecting skin characteristics or other biological characteristics. One or more of the layers can contain a wirelessly-chargeable printed battery, such as in an inductively coupled layer. Communications between layers can be performed using optical communications, such as using pulsing LEDs and photodiodes, or NFC. One or more layers can be semi-transparent. By laminating various circuit layers together to form a combination of programmable circuits, the only processing that needs to be done to build the completed circuit is lamination under atmospheric conditions. There is no need for complex processing, such as forming metal-filled vias between layers, which could result in delamination and contamination from moisture.

In one embodiment, one or more programmable circuits may be used, and in other embodiments, the circuits are specially designed for a particular function. Using programmable circuits greatly reduces production and design costs.

In another embodiment, the only vias through the circuit layers are for power from an external battery. The metal connection can instead be along an edge of the circuit layers, so no vias are required.

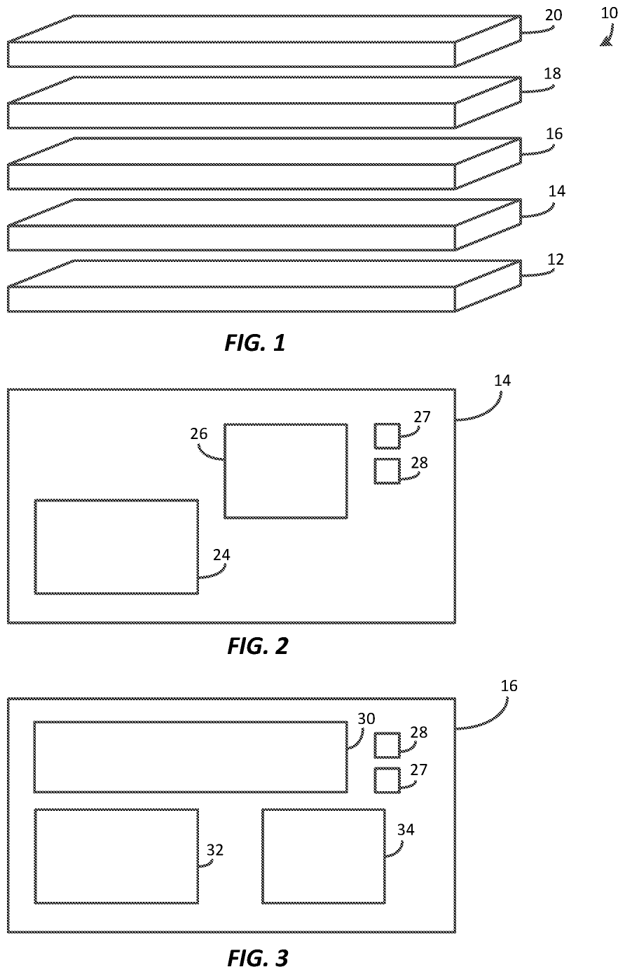

FIG. 1 is a perspective view of a layered circuit 10 that may be designed to perform many types of functions. In the example, a dielectric, flexible bottom substrate 12 may be a suitable plastic for providing physical robustness.

A programmable device layer 14, described later with reference to FIG. 6, includes a thin bottom substrate, a bottom patterned conductor layer, a printed device layer (such as printed semiconductor devices), a top patterned conductor layer, and a protective top layer. The layers may be essentially transparent. The conductor layers may allow programming, such as a customized interconnect pattern to form interconnected logic gates, LED drivers, etc. Such technology is described in Applicant's U.S. Pat. Nos. 9,913,371 and 10,499,499, incorporated by reference. Integrated circuits, such as memories or programmed processors, may also be mounted on any of the layers.

A display layer 16 may include microscopic inorganic, pre-formed LEDs that are printed in a particular pattern, or have a programmable connection, or include a patterned opaque mask, for displaying any suitable information to the user.

A communications layer 18 may include communication optics, an RF transmitter/receiver, a rechargeable printed battery using inductive coupling for wireless power transfer, or any other functionality. Any layer may include such communication devices and a thin battery.

A top layer 20 may include a sensor, such as a biological sensor for blood detection, skin detection, etc. The top layer 20 may be a protective layer.

The various layers are then laminated together under heat and pressure to permanently affix the layers together and hermetically seal the layers.

In one embodiment, the layers communicate vertically be pulsing LED light received by photosensors, such as photodiodes. In this way, low resistance metal vias are not needed, which avoids problems with delamination if the circuit layers are bent. In one embodiment, the communication speeds are in excess of 1 Mbs. The input and output signals may also be via light pulses.

FIG. 2 illustrates an example of the device layer 14. A printed battery 24 provides power to the semiconductor devices in the layer 14. A programmable circuit 26 is used to define the function of the layer 14. The programmable circuit 26 may be an integrated circuit or printed logic gates. A pulsed LED 27 and a photodiode 28 are used for vertical communications with other layers, or for input/output purposes. The various layers may be essentially transparent by using transparent conductors and a transparent substrate. A layer may communicate with multiple layers above and below it. If the layer 14 includes a sensor (e.g., a skin, blood, or heartrate sensor), it may be a top layer so the sensor can make direct contact with whatever is being sensed. Top electrodes may be used to measure the user's heart status, or a red LED and sensor may be used to detect aspects of the user's blood.

The layers may be used as light waveguides to cause the light to exit at predetermined areas.

FIG. 3 illustrates a display layer 16 having an LED display area 30, a printed battery 32, a programmable driver circuit 34 for the display and the optical communications, a pulsed LED 27 and a photodiode 28 for optical communications with other layers. The communications may be bidirectional since the layers can be made essentially transparent.

In another embodiment, the circuit 34 may be a programmed processor that stores and processes information. In another embodiment, the circuit 34 may be a pressure sensitive switch that applies power to the layers for a period of time when pressed by the user.

Near field communications (NFC) may also be used to communicate between layers, where opposing inductive coils transfer power between them. In the examples of FIGS. 2 and 3, the LED 26 and photodiode 28 may be represent flat NFC coils that oppose each other.

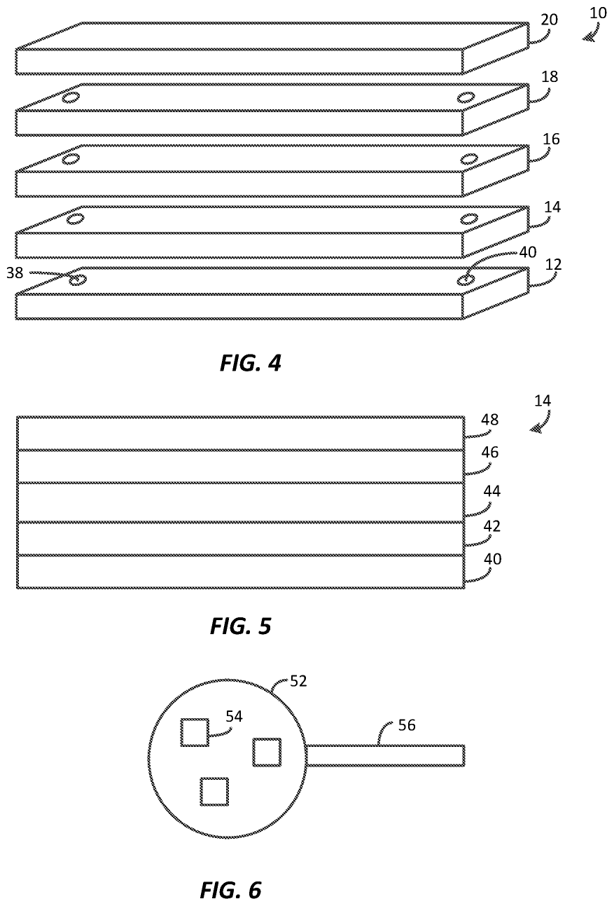

FIG. 4 illustrates how the various layers may include a pair of robust metal vias 38 and 40 for a supply voltage and ground. The power may be supplied by a printed battery in a power layer, or the power may be applied via an external power source. The external power source may apply power directly to terminals on a layer, or the power may be supplied wirelessly via an inductive coil formed on one or more of the layers. High frequency information signals may also be transmitted between layers using the vias 38 and 40. The power leads may also be formed on the sides of the layers, so no holes are needed in the layers for vias.

FIG. 5 illustrates in more detail a single layer that can be used as the device layer 14. A bottom substrate 40 has printed on it a patterned bottom conductor layer 42, which may be printed as a transparent ink.

Over the conductor layer 42 is printed semiconductor and/or passive components, such as transistors and diodes, in an active device layer 44, where the components have at least one terminal bonded to the conductor layer 42.

A patterned top conductor layer 46 connects various groups of the printed semiconductor components in parallel. A group of components connected in parallel perform the same function as a single one of the components in the group. Since printing components does not predetermine the exact placement of the components on the conductor layer 42, a printed “drop” of the component ink typically includes multiple identical components that are later connected in parallel. Therefore, a single small drop of the ink, when cured and connected to the conductor layers, performs as a single component. These cured drops may then be interconnected to form complex logic functions, including a state machine function for controlling other aspects of the circuitry. The functions may also include optical communications, as previously described.

A top, transparent protective layer 48 is then deposited on the device layer 14.

FIG. 6 illustrates a single drop of the device ink that is cured to effectively form a single component. The drop 52, in the example, contains three identical components 54, such as transistors or diodes. The precise locations of the components 54 in the drop 52 are random. The components 54 are connected in parallel by the conductor layers. A wire 56 in the patterned conductor layer connects to all the components in the cured drop, and interconnects with other components in the layer 14.

In one embodiment, the laminated layers form a blood or skin sensor circuit that the user keeps in his/her wallet and occasionally uses to detect a biological status. RF (e.g., Bluetooth or RFID) or optical communications may then communicate with the user's smartphone or another device to further process the data for display to the user. Alternatively, the laminated layers include a display so the user can directly see the results.

In another embodiment, the laminated circuit may be an inexpensive identification card containing information. A pre-formed memory chip may be connected within one of the layers to provide stored information or to store information. In one embodiment, one stacked circuit may wirelessly communicate with a separate stacked circuit, or with another device, for exchanging information between the circuits. This may be done optically or with RF.

The sensor layer may also detect gas, temperature, pressure, an ECG signal, humidity, etc.

The various layers may be laminated on textiles, such as clothing.

The various layers may be selected from many types of pre-designed layers, where the selected layers are simply laminated together to achieve an overall function. One or more layers may be programmable with a printed conductor pattern, such as to achieve a complex logic function. The layers may also form an adhesive patch for the user's skin, such as to measure and communicate glucose information.

A pressure-sensitive switch may be included in one or more of the layers for turning on an internal power switch for a certain time when the user squeezes the stacked layers.

Each layer can be tested individually prior to lamination to determine if the layer is defect-free. Various layers may be fabricated and stored prior to designating them for a particular function, which greatly reduces the cost of production. Programming may be performed at any time. The layers should be planarized prior to lamination.

Any layer may also include any type of thin integrated circuit that is mounted onto a conductor layer. The layers are planarized prior to lamination.

The input/output signals for the stack of layers may be by light or NFC or both. For example, if IR is desired for input or output (or for vertical communication between layers), an IR LED or IR photodiode (or other sensor) is used in the layers. Smartphones are equipped with IR detectors and IR transmitters, so the stacked layers can communicate with smartphones using an appropriate application. A smartphone camera can also detect light pulses (such as blue or white light) from an input/output layer of the stack of layers. The smartphone flash can also communicate optically with the stack of layers. One stack of layers may also communicate directly with another stack of layers, such as for exchanging information. By using optical communications, the information transferred is very secure.

The layers may effectively be an IR patch that is used for identification or authentication by using unique codes. The display can display information about the identification or authentication.

The card can be inserted into a card reader and read optically for identification purposes or for payment purposes.

The layers may communicate information over the internet via a smartphone.

The stack of layers may be inexpensive so may be disposable.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A circuit structure comprising:
a first layer configured to perform a first electric function;
a second layer laminated onto the first layer, the second layer configured to perform a second electronic function;
a first wireless communications device within the first layer; and
a second wireless communications device within the second layer, wherein the first layer and second layer communicate vertically via the first wireless communication device and the second wireless communications device.

2. The structure of claim 1 wherein,
the first wireless communications device comprises at least one of a first LED and a first photo-sensitive device, and
the second wireless communications device comprises at least one of a second LED and a second photo-sensitive device.

3. The structure of claim 1 wherein,
the first wireless communications device comprises a first near field communications circuit, and
the second wireless communications device comprises a second near field communications circuit.

4. The structure of claim 1 wherein the first layer contains a programmable circuit.

5. The structure of claim 4 wherein the programmable circuit is an integrated circuit.

6. The structure of claim 4 wherein the programmable circuit is a printed circuit.

7. The structure of claim 1 wherein the first layer comprises a wireless input or output circuit for communicating with an external device.

8. The structure of claim 1 wherein the first layer includes a rechargeable battery.

9. The structure of claim 1 wherein the first layer includes a sensor device for detecting information from an external source.

10. The structure of claim 1 wherein first layer includes an optical transmitter for communicating with an external device.

11. The structure of claim 1 wherein the first layer includes a memory circuit.

12. A method of forming a circuit comprising:
providing a first layer configured to perform a first electric function, the first layer including a first wireless communications device;
providing a second layer configured to perform a second electronic function, the second layer including a second wireless communications device; and
laminating the first layer to the second layer so that the first layer and the second layer communicate vertically via the first wireless communication device and the second wireless communications device.

13. The method of claim 12 wherein the first layer and the second layer communicate via at least one LED and at least one photo-sensitive device.

14. The method of claim 12 wherein the first layer and the second layer communicate via near field communication circuits.

15. The method of claim 12 wherein the first layer contains a programmable circuit.

16. The method of claim 15 wherein the programmable circuit is an integrated circuit.

17. The method of claim 15 wherein the programmable circuit comprises a printed circuit.

18. The method of claim 12 wherein the first layer comprises a wireless input or output circuit for communicating with an external device.

19. The method of claim 18 wherein wireless input or output circuit includes an optical transmitter for communicating with the external device.

20. The method of claim 12 wherein the first layer includes a wirelessly rechargeable battery.
